(19) United States
(12) Patent Application Publication
(10) Pub. No.: US 2024/0258307 A1
(43) Pub. Date: Aug. 1, 2024

(54) ELECTRONIC ELEMENT AND CIRCUIT DEVICE

(71) Applicant: Murata Manufacturing Co., Ltd., Nagaokakyo-shi (JP)

(72) Inventor: Takaaki MIYASAKO, Nagaokakyo-shi (JP)

(21) Appl. No.: 18/634,273

(22) Filed: Apr. 12, 2024

Related U.S. Application Data
(63) Continuation of application No. PCT/JP2022/042259, filed on Nov. 14, 2022.

(30) Foreign Application Priority Data
Nov. 17, 2021 (JP) 2021-187089

(51) Int. Cl. H01L 27/07; H01F 27/28; H01G 4/33; H01G 4/40; H01L 29/786

(52) U.S. Cl. CPC H01L 27/0727; H01F 27/28; H01G 4/33; H01G 4/40; H01L 29/78696

(57) ABSTRACT

An electronic element and a circuit device is provided that varies a physical quantity of a passive element in a wide range including when the physical quantity is zero. A variable capacitance element includes a switch and an element that configures a capacitor. The switch has a source electrode, a drain electrode, a channel forming film that overlaps at least a part of the source and drain electrodes, a gate insulating film that overlaps the channel forming film, and a gate electrode on the gate insulating film. The element has a terminal electrode electrically connected to the source electrode, and a terminal electrode that configures a capacitor between the terminal electrode and a part of the drain electrode by sandwiching a dielectric layer therebetween or being in contact with the dielectric layer. The dielectric layer and the gate insulating film are the same insulating film.

### CROSS REFERENCE TO RELATED APPLICATIONS

This application is a continuation of International Application No. PCT/JP2022/042259, filed Nov. 14, 2022, which claims priority to Japanese Patent Application No. 2021-187089, filed Nov. 17, 2021, the entire contents of each of which are hereby incorporated by reference in their entirety.

### TECHNICAL FIELD

The present invention relates to an electronic element that varies a physical quantity of a passive element, and a circuit device including the electronic element.

### BACKGROUND

As an electronic element that can vary a physical quantity of a passive element, for example, a variable capacitance element capable of varying capacitance (e.g., a capacitor) currently exists. For example, Japanese Unexamined Patent Application Publication No. 2002-373829 (hereinafter “Patent Document 1”) discloses a variable capacitance element in which a plate-shaped movable comb-tooth electrode and a plate-shaped fixed comb-tooth electrode that faces the movable comb-tooth electrode with a minute gap interposed therebetween are provided by using a micromachining technique. In addition, an article entitled “Evaluation of Channel Modulation in In2O3/(Bi, La) 4Ti3O12 Ferroelectric-Gate Thin Film Transistors by Capacitance-Voltage Measurements”, to Eisuke et al., Ferroelectrics, 429, pp. 15 to 21, June 2012 (hereinafter “Non-Patent Document 1”) discloses a variable capacitance element with a two-terminal structure using an ON/OFF operation of a field effect transistor (FET).

The variable capacitance element disclosed in Patent Document 1 has a small range of variable capacitance, typically only a few times the capacitance before variation, and the range of variable capacitance is insufficient for applications such as a wideband communication system or a power supply circuit, where significant frequency modulation is required. In addition, the variable capacitance element disclosed in Patent Document 1 can vary capacitance by changing a distance between the facing comb-tooth electrodes. Therefore, in the variable capacitance element, there is a limitation on the distance that can be changed, and it is not possible to theoretically set the capacitance to zero.

Further, in the variable capacitance element disclosed in Non-Patent Document 1, increasing the film thickness of a gate insulating film (e.g., dielectric) in order to increase the withstand voltage results in a capacitance value that decreases in inverse proportion to the film thickness.

### SUMMARY OF THE INVENTION

In view of the foregoing, an electronic element and a circuit device is provided that is configured to vary a physical quantity of a passive element in a wide range including a case where the physical quantity is zero.

Thus, in an exemplary aspect, an electronic element is provided that includes a switch that configures an electric field effect transistor; and an element that is electrically connected to the switch part and configures a passive element. The switch has a source electrode, a drain electrode, a channel forming film that overlaps at least a part of the source electrode and a part of the drain electrode, a gate insulating film that overlaps the channel forming film, and a gate electrode on the gate insulating film. The element has a first terminal electrode that is electrically connected to the source electrode, and a second terminal electrode that configures the passive element between the second terminal electrode and a part of the drain electrode by sandwiching a dielectric layer therebetween or being in contact with the dielectric layer. Moreover, the dielectric layer and the gate insulating film are the same insulating film.

According to another exemplary aspect, a circuit device is provided that includes a circuit wiring line; and the above-described electronic element that is electrically connected to the circuit wiring line.

According to the exemplary aspects of the present disclosure, the electronic element includes the element having the first terminal electrode and the second terminal electrode that configures the passive element between the second terminal electrode and a part of the drain electrode by sandwiching the dielectric layer therebetween or in contact with the dielectric layer. Therefore, the physical quantity of the passive element can be varied in a wide range including when the physical quantity is zero.

### BRIEF DESCRIPTION OF DRAWINGS

FIG. 1 is a cross-sectional view illustrating a configuration of a variable capacitance element according to a first exemplary embodiment.

FIG. 2 is a plan view illustrating the configuration of the variable capacitance element according to the first exemplary embodiment.

FIG. 3(a)-FIG. 3(e) are cross-sectional views illustrating a method of manufacturing the variable capacitance element according to the first exemplary embodiment.

FIG. 4 is a circuit diagram of a multivalued variable capacitance element according to the first exemplary embodiment.

FIG. 5 is a cross-sectional view illustrating a configuration of a variable capacitance element according to a first modification of the first exemplary embodiment.

FIG. 6 is a cross-sectional view illustrating a configuration of a variable capacitance element according to a second modification of the first exemplary embodiment.

FIG. 7 is a cross-sectional view illustrating a configuration of a variable capacitance element according to a third modification of the first exemplary embodiment.

FIG. 8 is a cross-sectional view illustrating a configuration of a variable capacitance element according to a second exemplary embodiment.

FIG. 9 is a cross-sectional view illustrating a configuration of a variable capacitance element according to a first modification of the second exemplary embodiment.

FIG. 10 is a cross-sectional view illustrating a configuration of a variable capacitance element according to a second modification of the second exemplary embodiment.

FIG. 11 is a cross-sectional view illustrating a configuration of a variable capacitance element according to a third modification of the second exemplary embodiment.

FIG. 12 is a cross-sectional view illustrating a configuration of a variable capacitance element according to a fourth modification of the second exemplary embodiment.

FIG. 13 is a cross-sectional view illustrating a configuration of a variable capacitance element according to a third exemplary embodiment.

FIG. 14 is a plan view illustrating the configuration of the variable capacitance element according to the third exemplary embodiment.

FIG. 15 is a cross-sectional view illustrating a configuration of a variable capacitance element according to a first modification of the third exemplary embodiment.

FIG. 16 is a cross-sectional view illustrating a configuration of a variable capacitance element according to a second modification of the third exemplary embodiment.

FIG. 17 is a cross-sectional view illustrating a configuration of a variable capacitance element according to a third modification of the third exemplary embodiment.

FIG. 18 is a cross-sectional view illustrating a configuration of a variable inductance element according to a fourth exemplary embodiment.

FIG. 19(a)-FIG. 19(b) are equivalent circuit diagrams of the variable inductance element according to the fourth exemplary embodiment.

FIG. 20 is a plan view illustrating a configuration of a variable inductance element according to a modification of the fourth exemplary embodiment.

FIG. 21 is a cross-sectional view illustrating the configuration of the variable inductance element according to the modification of the fourth exemplary embodiment.

FIG. 22 is a cross-sectional view illustrating a configuration of a variable capacitance element according to a fifth fourth exemplary embodiment.

### DETAILED DESCRIPTION OF EMBODIMENTS

Hereinafter, an electronic element according to exemplary embodiments of the present disclosure will be described in detail with reference to the drawings. In particular, in the electronic element according to the embodiments of the present disclosure, an electronic element configured to vary a physical quantity of a passive element will be described. It is noted that identical reference numerals in the drawings represent the same or equivalent portions. In addition, in the present disclosure, when the physical quantity of the passive element is zero is not limited to a case where the physical quantity is completely zero, and the physical quantity need only be a physical quantity equal to or less than a predetermined quantity (for example, equal to or less than one-ten-thousandth), which can be considered as zero for a state with the physical quantity. Further, the electronic element can also impart memory characteristics because the electronic element can be configured to switch between a state with the physical quantity of the passive element and a state with zero physical quantity.

### First Exemplary Embodiment

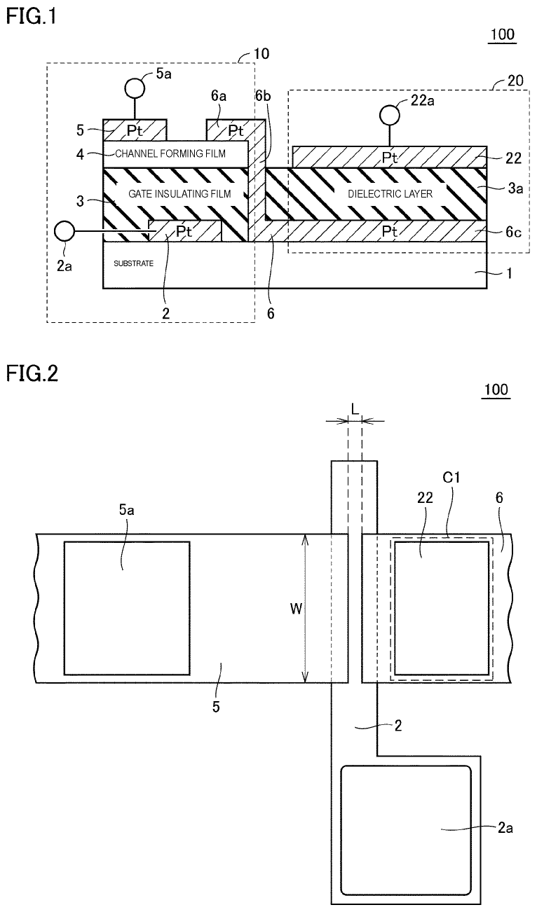

In a first exemplary embodiment, a variable capacitance element in which a passive element is a capacitor and a physical quantity to be varied is capacitance will be described. In particular, in the first exemplary embodiment, a variable capacitance element that is configured to switch between a state with capacitance and a state with zero capacitance (hereinafter, also referred to as a state with no capacitance) will be described with reference to the drawings. FIG. 1 is a cross-sectional view illustrating a configuration of a variable capacitance element 100 according to the first exemplary embodiment. FIG. 2 is a plan view illustrating a configuration of the variable capacitance element 100 according to the first exemplary embodiment.

The variable capacitance element 100 shown in FIG. 1 includes a switch part 10 (also referred to simply as a “switch”) that configures (e.g., forms) an electric field effect transistor formed on a semiconductor substrate 1, and an element part 20 (also referred to simply as an “element”) that is electrically connected to the switch part 10 and configures (e.g., forms) a capacitor. The element part 20 and the switch part 10 are horizontally disposed on the semiconductor substrate 1 in the exemplary aspect.

The switch part 10 has a gate electrode 2, a gate insulating film 3, a channel forming film 4, a source electrode 5, and a drain electrode 6. In the switch part 10 shown in FIG. 1, the gate electrode 2 is formed on the semiconductor substrate 1, the gate insulating film 3 and the channel forming film 4 are sequentially formed to overlap the gate electrode 2, and the source electrode 5 and a part of the drain electrode 6 are respectively formed thereon.

More specifically, the switch part 10 is an oxide field effect transistor (FET). For example, lanthanum aluminate (LAO) can be used for the semiconductor substrate 1, and the gate electrode 2 is formed on the semiconductor substrate 1 in a predetermined pattern shown in FIG. 2 by using platinum (Pt). For example, a La-HfO₂ film having a film thickness of 70 nm is used for the gate insulating film 3, and for example, an IZO film having a film thickness of 25 nm is used for the channel forming film 4. According to an exemplary aspect, the source electrode 5 and the drain electrode 6 are formed on the channel forming film 4 of the IZO film in a predetermined pattern shown in FIG. 2 by using platinum (Pt). A terminal electrode 5a (first terminal electrode) is provided over the source electrode 5 shown in FIG. 2, but the source electrode 5 itself may be used as the terminal electrode 5a. In the switch part 10, for example, a channel width W is 100 μm, and a channel length L is 10 μm.

As shown in FIG. 1, the drain electrode 6 extends not only to a portion formed on the channel forming film 4 but also to a portion configuring the element part 20. Specifically, the drain electrode 6 includes an electrode 6a configuring the switch part 10, an electrode 6c configuring the element part 20, and an electrode 6b connecting the electrode 6a and the electrode 6c to each other. The electrode 6a is a part of the drain electrode 6 formed on the channel forming film 4. The electrode 6c is a part of the drain electrode 6 formed on the semiconductor substrate 1. The electrode 6b is a part of the drain electrode 6 formed to penetrate the gate insulating film 3.

The element part 20 is a capacitor provided on a part (an upper portion of the electrode 6c) of the drain electrode 6. The element part 20 includes the electrode 6c, a dielectric layer 3a formed of the same insulating film as the gate insulating film 3, and a terminal electrode 22 (second terminal electrode) made of platinum (Pt) and formed to overlap the dielectric layer 3a. The terminal electrode 22 is formed in a predetermined pattern shown in FIG. 2. The gate electrode 2 is drawn from an overlapping region of the source electrode 5 and the drain electrode 6 as shown in FIG. 2, and a control electrode terminal 2a is provided on the gate electrode 2.

The element part 20 configures (e.g., forms) a capacitor with the dielectric layer 3a provided between a part (electrode 6c) of the drain electrode 6 and the terminal electrode 22. The capacitor is a portion C1 in which the drain electrode 6 and the terminal electrode 22 overlap each other in a plan view as shown in FIG. 2. The drain electrode 6 is a floating electrode and is not electrically directly connected to the terminal electrode 5a of the variable capacitance element 100.

In the variable capacitance element 100, when the switch part 10 is in an OFF state, a gate voltage equal to or higher than a threshold value is not applied to the gate electrode 2, so that an electron depletion layer is present at a position of the channel forming film 4 overlapping the gate electrode 2 in a plan view, and the source electrode 5 and the drain electrode 6 are not electrically connected. Therefore, in the variable capacitance element 100, a voltage is applied only to the source electrode 5, and no voltage is applied between the electrode 6c and the terminal electrode 22, so that the capacitor is not configured.

On the other hand, in the variable capacitance element 100, when the switch part 10 is in an ON state, a gate voltage equal to or higher than the threshold value is applied to the gate electrode 2, and a channel is formed, so that the source electrode 5 and the drain electrode 6 are electrically connected. Therefore, in the variable capacitance element 100, a voltage is applied to the source electrode 5 and the drain electrode 6, and a voltage is also applied between the electrode 6c and the terminal electrode 22, so that the capacitor is configured.

That is, in the variable capacitance element 100, the switch part 10 is configured to operate in an ON/OFF manner to switch between a state with no capacitor and a state with a capacitor, thereby turning the capacitor ON/OFF. The variable capacitance element 100 is divided into the switch part 10 that operates in an ON/OFF manner by the voltage applied to the gate electrode 2 (control electrode terminal 2a), and the element part 20 that operates between a part (electrode 6c) of the drain electrode 6 and a terminal 22a of the terminal electrode 22 (second terminal electrode) through the terminal electrode 5a (first terminal electrode), and operates with three terminals.

In addition, in the variable capacitance element 100, since the gate electrode 2 (control electrode terminal 2a) of the switch part 10 and the terminal 22a of the terminal electrode 22 (second terminal electrode) of the element part 20 are electrically isolated from each other, the operation of the switch part 10 is not affected by a signal on an element part 20 side. While the terminal electrode 5a (first terminal electrode) and the terminal 22a of the terminal electrode 22 (second terminal electrode) of the variable capacitance element 100 are connected to a filter circuit or the like, the control electrode terminal 2a for switching between the presence or absence of capacitance is connected to a circuit different from the filter circuit. Therefore, the probability of a signal applied to the control electrode terminal 2a being affected by the signal of the filter circuit is low.

Further, in the variable capacitance element 100, the electrical resistance of the channel forming film 4 between the source electrode 5 and the drain electrode 6 can be reduced by shortening the channel length L of the switch part 10. Therefore, in the variable capacitance element 100, in order to switch between the presence or absence of the capacitance at a high speed, it can be addressed by improving the switching speed (e.g., a time constant) of the switch part 10.

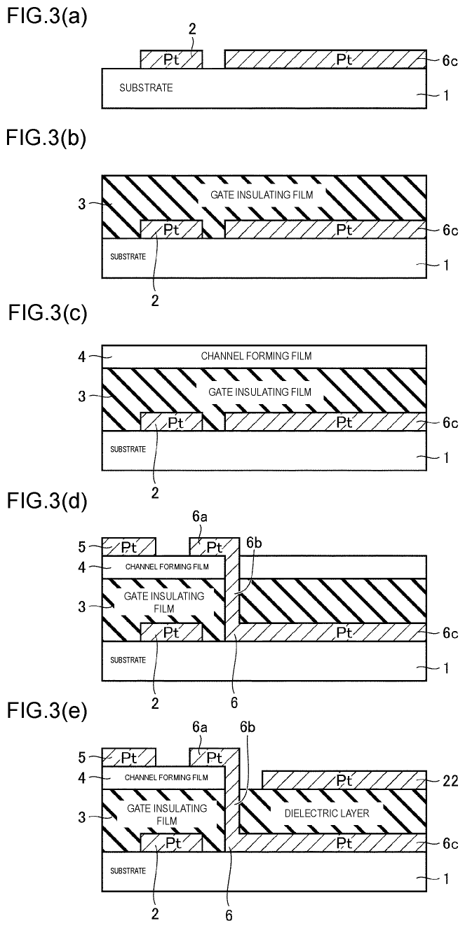

Next, a method of manufacturing the variable capacitance element 100 will be described with reference to the drawings. FIG. 3(a)-FIG. 3(e) are cross-sectional views illustrating the method of manufacturing the variable capacitance element according to the first exemplary embodiment. First, in FIG. 3(a), on a prepared (100) surface of the semiconductor substrate 1 of lanthanum aluminate (LAO), the gate electrode 2 and a part (electrode 6c) of the drain electrode 6 are formed by using platinum (Pt) with a film thickness of 80 nm. Specifically, the gate electrode 2 is formed by using a photolithography technique to form a photoresist having a predetermined pattern on the (100) surface of the semiconductor substrate 1, and then forming a film using platinum (Pt) through radio frequency (RF) sputtering and removing the photoresist by lift-off.

In FIG. 3(b), the gate insulating film 3 having a film thickness of 70 nm is formed to overlap the surface of the semiconductor substrate 1 on which the gate electrode 2 and a part (electrode 6c) of the drain electrode 6 are formed. Specifically, the gate insulating film 3 is formed by using a chemical solution deposition (CSD) method to form a film through spin-coating of a La-HfO₂ solution onto the surface of the semiconductor substrate 1, on which the gate electrode 2 is formed, drying the film at 150° C., and then crystallizing the film through firing in an oxygen atmosphere at 800° C.

In FIG. 3(c), the channel forming film 4 having a film thickness of 25 nm is formed to overlap the gate insulating film 3. Specifically, the channel forming film 4 is formed by using a chemical solution deposition (CSD) method to form a film through spin-coating of an IZO solution onto the gate insulating film 3 in an overlapping manner, drying the film at 150° C., and then crystallizing the film through firing in an oxygen atmosphere at 500° C.

In FIG. 3(d), a part (electrode 6b) of the drain electrode 6 penetrating the gate insulating film 3 and the channel forming film 4 is formed. Specifically, the electrode 6b is, for example, a via conductor in which a hole penetrating the gate insulating film 3 and the channel forming film 4 is formed at a position overlapping the electrode 6c and the formed hole is filled with a conductive material. Further, in FIG. 3(d), the source electrode 5 and a part (electrode 6a) of the drain electrode 6 are formed on the channel forming film 4 by using platinum (Pt) with a film thickness of 80 nm. Specifically, the source electrode 5 and the electrode 6a are formed by forming a photoresist having a predetermined pattern on the channel forming film 4 using a photolithography technique, and then forming a film using platinum (Pt) through radio frequency (RF) sputtering and removing the photoresist by lift-off. The electrode 6a and the electrode 6b are electrically connected to each other.

In FIG. 3(e), the channel forming film 4 provided above a part (electrode 6c) of the drain electrode 6 is removed, and the terminal electrode 22 is formed using platinum (Pt) with a film thickness of 80 nm. Specifically, the terminal electrode 22 is formed by removing the channel forming film 4, forming a photoresist having a predetermined pattern on the dielectric layer 3a using a photolithography technique, and then forming a film using platinum (Pt) through radio frequency (RF) sputtering and removing the photoresist by lift-off.

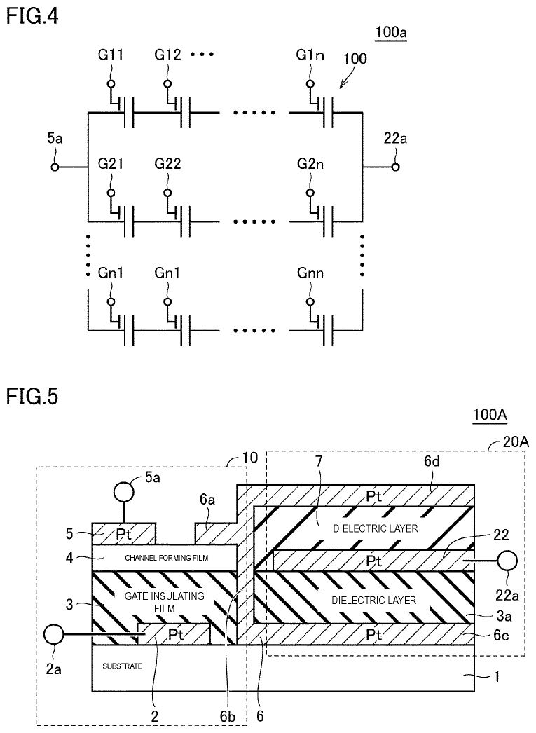

The variable capacitance element 100 described above is an element that is configured to switch between a state with no capacitor and a state with a capacitor. However, it is noted that a multivalued variable capacitance element can be configured by forming a plurality of variable capacitance elements 100 on the semiconductor substrate 1 in a matrix shape. FIG. 4 is a circuit diagram of a multivalued variable capacitance element 100a according to the first exemplary embodiment.

FIG. 4 shows a circuit diagram of the variable capacitance element 100a in which n×n variable capacitance elements 100 shown in FIG. 1 are connected in a matrix shape. In the variable capacitance element 100a shown in FIG. 4, the terminal electrode 5a (first terminal electrode) and the terminal electrode 22 (second terminal electrode) are used in common to the n×n variable capacitance elements 100. However, the control electrode terminals 2a of the n×n variable capacitance elements 100 are respectively and separately provided and are shown as a terminal G11 to a terminal Gnn in FIG. 4. By supplying signals to the terminal G11 to the terminal Gnn, the required number of variable capacitance elements 100 can be controlled to the ON state to obtain the required capacitance, so that the capacitance of the variable capacitance element 100a can be multivalued.

As described above, the variable capacitance element 100 according to the first exemplary embodiment includes the switch part 10 that configures (e.g., forms) an electric field effect transistor, and the element part 20 that is electrically connected to the switch part 10 and configures (e.g., forms) a capacitor. The switch part 10 has the source electrode 5, the drain electrode 6, the channel forming film 4 formed to overlap at least a part of the source electrode 5 and a part of the drain electrode 6, the gate insulating film 3 formed to overlap the channel forming film 4, and the gate electrode 2 formed to overlap the gate insulating film 3. The element part 20 has the terminal electrode 5a (first terminal electrode) that is electrically connected to the source electrode 5, and the terminal electrode 22 (second terminal electrode) that configures (e.g., forms) a capacitor between the terminal electrode 22 and a part (electrode 6c) of the drain electrode 6 with the dielectric layer 3a sandwiched therebetween. The dielectric layer 3a and the gate insulating film 3 are the same insulating film.

As a result, the variable capacitance element 100 according to the first exemplary embodiment configures (e.g., forms) a capacitor between a part (electrode 6c) of the drain electrode 6 and the terminal electrode 22 with the dielectric layer 3a sandwiched therebetween, which is formed of the same insulating film as the gate insulating film 3, so that the capacitance can be varied in a wide range including a case where the capacitance is zero.

In addition, in the variable capacitance element 100, by using the same insulating film for the dielectric layer 3a and the gate insulating film 3, the number of processes can be reduced. Further, in the variable capacitance element 100, by horizontally forming the switch part 10 and the element part 20 on the semiconductor substrate 1 without forming the element part 20 to overlap the switch part 10, it is possible to select a dielectric material that requires a process which may adversely affect the switch part 10 such as high-temperature processing, a dielectric material that may be affected by the orientation of the underlying material, or the like for the dielectric layer 3a, and this improves the selectivity of materials.

According to an exemplary aspect of the variable capacitance element 100, a part (electrode 6c) of the drain electrode 6 is formed on a surface of the dielectric layer 3a on the same side as the surface of the gate insulating film 3 on which the gate electrode 2 is formed, and the terminal electrode 22 is formed on a surface of the dielectric layer 3a on a side opposite to the surface of the gate insulating film 3 on which the gate electrode 2 is formed.

### Modification 1-1

In the variable capacitance element 100, as shown in FIG. 1, a capacitor is configured with the dielectric layer 3a disposed between a part (electrode 6c) of the drain electrode 6 and the terminal electrode 22. In the variable capacitance element 100, in order to further increase the capacitance of the capacitor, a configuration in which a plurality of dielectric layers configuring the element part 20 are stacked is conceivable. FIG. 5 is a cross-sectional view illustrating a configuration of a variable capacitance element 100A according to a first modification of the first exemplary embodiment. In the variable capacitance element 100A shown in FIG. 5, the same configurations as those of the variable capacitance element 100 shown in FIG. 1 are designated by the same reference numerals, and detailed description thereof will not be repeated.

The variable capacitance element 100A shown in FIG. 5 includes the switch part 10 that configures (e.g., forms) an electric field effect transistor formed on the semiconductor substrate 1, and an element part 20A that is electrically connected to the switch part 10 and configures (e.g., forms) a passive element.

The element part 20A configures (e.g., forms) a capacitor with the dielectric layer 3a provided between a part (electrode 6c) of the drain electrode 6 and the terminal electrode 22 and further configures (e.g., forms) a capacitor with a dielectric layer 7 provided between the terminal electrode 22 and a part (electrode 6d) of the drain electrode 6. Moreover, the dielectric layers sandwiched between a part (electrodes 6c and 6d) of the drain electrode 6 and the terminal electrode 22 include the dielectric layer 3a (first dielectric layer) formed of the same insulating film as the gate insulating film 3, and the dielectric layer 7 (second dielectric layer) formed of an insulating film different from the gate insulating film 3.

According to an exemplary aspect, the element part 20A configures (e.g., forms) a plurality of layers of capacitors by sequentially stacking a part (electrode 6c) of the drain electrode 6, the dielectric layer 3a (first dielectric layer), the terminal electrode 22, the dielectric layer 7 (second dielectric layer), and a part (electrode 6d) of the drain electrode 6. Consequently, the variable capacitance element 100A including the element part 20A can further increase the capacitance of the capacitor. For example, when the capacitance of the capacitor configured with the dielectric layer 3a is denoted by C_{A} and the capacitance of the capacitor configured with the dielectric layer 7 is denoted by C_{B}, the variable capacitance element 100A, when the switch part 10 is in an ON state, has a capacitance C_{ON} represented by C_{ON}=C_{A}+C_{B}.

The dielectric layer 3a and the dielectric layer 7 may have the same film thickness or different film thicknesses. Further, the dielectric layer 3a and the dielectric layer 7 may be the same dielectric material or may be different dielectric materials. Specifically, a dielectric material (for example, a (Ba, Sr) TiO₃-based perovskite oxide or the like) having a dielectric-constant that depends on a DC bias voltage may be used for either the dielectric layer 3a or the dielectric layer 7. By using the dielectric material for either the dielectric layer 3a or the dielectric layer 7, the capacitance C_{ON} can be finely adjusted when the switch part 10 is in an ON state. For example, when the dielectric material is used for the dielectric layer 7, and a DC bias voltage (V_{DC}) is applied to the terminal electrode 22, the variable capacitance element 100A, when the switch part 10 is in an ON state, has a capacitance C_{ON} represented by C_{ON}=C_{A}+C_{B} (V_{DC}). Since C_{B} (V_{DC}) changes due to the DC bias voltage (V_{DC}) applied to the terminal electrode 22, the capacitance C_{ON} can be accurately and finely adjusted.

In the variable capacitance element 100A, the element part 20A configures (e.g., forms) a two-layer capacitor by sequentially stacking a part (electrode 6c) of the drain electrode 6, the dielectric layer 3a (first dielectric layer), the terminal electrode 22, the dielectric layer 7 (second dielectric layer), and a part (electrode 6d) of the drain electrode 6, but three or more layers of capacitors may be configured.

### Modification 1-2

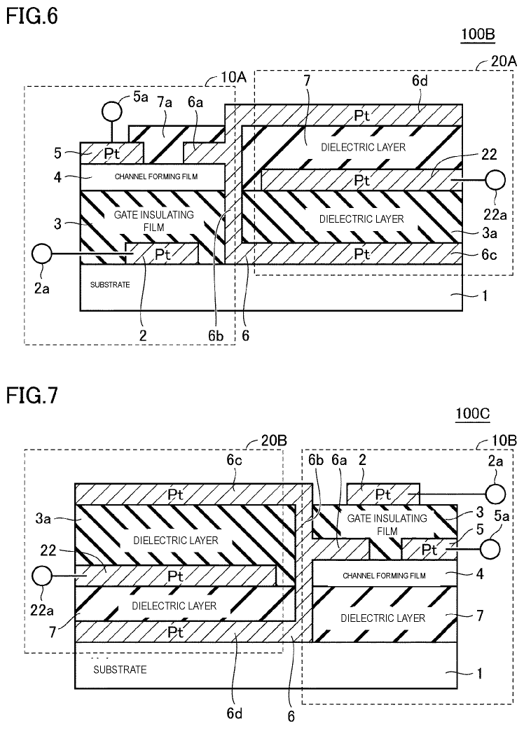

FIG. 6 is a cross-sectional view illustrating a configuration of a variable capacitance element 100B according to a second modification of the first exemplary embodiment. In the variable capacitance element 100B shown in FIG. 6, the same configurations as those of the variable capacitance element 100A shown in FIG. 5 are designated by the same reference numerals, and detailed description thereof will not be repeated.

The variable capacitance element 100B shown in FIG. 6 includes a switch part 10A that configures (e.g., forms) an electric field effect transistor formed on the semiconductor substrate 1, and the element part 20A that is electrically connected to the switch part 10A and configures (e.g., forms) a passive element.

The switch part 10A has the gate electrode 2, the gate insulating film 3, the channel forming film 4, the source electrode 5, the drain electrode 6, and a passivation film 7a. In the switch part 10A shown in FIG. 6, the gate electrode 2 is formed on the semiconductor substrate 1, the gate insulating film 3 and the channel forming film 4 are sequentially formed to overlap the gate electrode 2, and the source electrode 5 and a part of the drain electrode 6 are respectively formed thereon and are covered with the passivation film 7a.

In the variable capacitance element 100B, the passivation film 7a is formed by covering the channel forming film 4 between the source electrode 5 and the drain electrode 6 with a part of the dielectric layer 7. The passivation film 7a can suppress the degradation of the characteristics of the switch part 10. In addition, by forming the passivation film 7a using a part of the dielectric layer 7, the passivation film can be formed by covering the channel forming film 4 without adding a separate process.

### Modification 1-3

FIG. 7 is a cross-sectional view illustrating a configuration of a variable capacitance element 100C according to a third modification of the first exemplary embodiment. In the variable capacitance element 100C shown in FIG. 7, the same configurations as those of the variable capacitance element 100A shown in FIG. 5 are designated by the same reference numerals, and detailed description thereof will not be repeated.

According to an exemplary aspect, the variable capacitance element 100C shown in FIG. 7 includes a switch part 10B that configures (e.g., forms) an electric field effect transistor formed on the semiconductor substrate 1, and an element part 20B that is electrically connected to the switch part 10B and configures (e.g., forms) a passive element.

The switch part 10B includes the gate electrode 2, the gate insulating film 3, the channel forming film 4, the source electrode 5, and the drain electrode 6. However, the switch part 10B employs a top-gate structure instead of a bottom-gate structure as in the switch part 10 shown in FIG. 1. In the switch part 10B, the channel forming film 4 is formed on the dielectric layer 7 in an overlapping manner, the source electrode 5 and the drain electrode 6 are respectively formed on the channel forming film 4, the gate insulating film 3 is formed on the source electrode 5 and the drain electrode 6, and the gate electrode 2 is formed on the gate insulating film 3.

The element part 20B, because a part (electrode 6d) of the drain electrode 6 is formed on a semiconductor substrate 1 side, configures (e.g., forms) a two-layer capacitor by sequentially stacking a part (electrode 6d) of the drain electrode 6, the dielectric layer 7 (second dielectric layer), the terminal electrode 22, the dielectric layer 3a (first dielectric layer), and a part (electrode 6c) of the drain electrode 6.

According to an exemplary aspect, the variable capacitance element 100C includes the switch part 10B having the top-gate structure, but the same effect as that of the variable capacitance element 100A employing the switch part 10 having the bottom-gate structure can be obtained. In addition, a switch part having the top-gate structure may be employed for the switch part of the variable capacitance element 100 shown in FIG. 1.

### Second Exemplary Embodiment

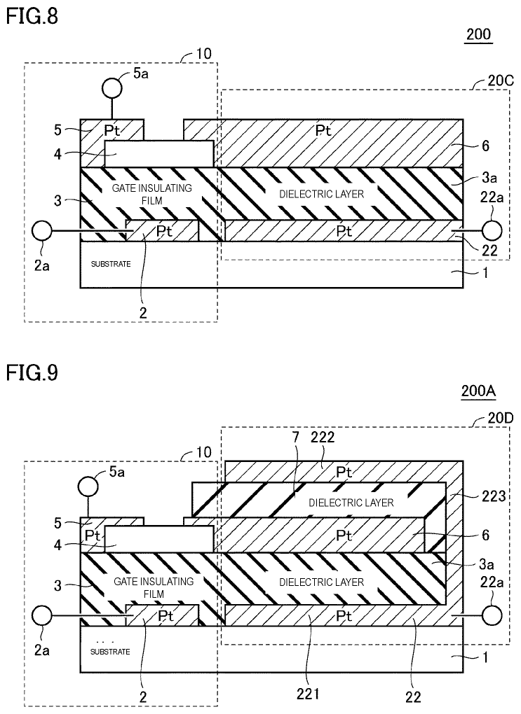

In the variable capacitance element 100 according to the first exemplary embodiment, a configuration in which a part (electrode 6c) of the drain electrode 6, which is the floating electrode, is on the semiconductor substrate 1 side in the element part 20 has been described. In the variable capacitance element according to a second exemplary embodiment, a configuration in which the terminal electrode is formed on the semiconductor substrate side in the element part will be described. In particular, FIG. 8 is a cross-sectional view illustrating a configuration of a variable capacitance element 200 according to the second exemplary embodiment. In the variable capacitance element 200 shown in FIG. 8, the same configurations as those of the variable capacitance element 100 shown in FIG. 1 are designated by the same reference numerals, and detailed description thereof will not be repeated.

The variable capacitance element 200 shown in FIG. 8 includes the switch part 10 that configures (e.g., forms) an electric field effect transistor, and an element part 20C that is electrically connected to the switch part 10 and configures (e.g., forms) a passive element. The element part 20C and the switch part 10 are horizontally disposed on the semiconductor substrate 1.

Moreover, the switch part 10 has the gate electrode 2, the gate insulating film 3, the channel forming film 4, the source electrode 5, and the drain electrode 6. In the switch part 10 shown in FIG. 8, the gate electrode 2 is formed on the semiconductor substrate 1, the gate insulating film 3 and the channel forming film 4 are sequentially formed to overlap the gate electrode 2, and a part of the source electrode 5 and a part of the drain electrode 6 are respectively formed thereon.

As shown in FIG. 8, the drain electrode 6 extends not only to a portion formed on the channel forming film 4 but also to a portion configuring the element part 20C. The element part 20C is a capacitor provided in a part of the drain electrode 6. The element part 20C includes a part of the drain electrode 6, the dielectric layer 3a formed of the same insulating film as the gate insulating film 3, and the terminal electrode 22 (second terminal electrode) made of platinum (Pt) and formed to overlap the dielectric layer 3a. The drain electrode 6 is a floating electrode and is not electrically directly connected to the terminal electrode 5a of the variable capacitance element 200.

In the variable capacitance element 200, when the switch part 10 is in an OFF state, a gate voltage equal to or higher than a threshold value is not applied to the gate electrode 2, so that an electron depletion layer is present at a position of the channel forming film 4 overlapping the gate electrode 2 in a plan view, and the source electrode 5 and the drain electrode 6 are not electrically connected. Therefore, in the variable capacitance element 200, a voltage is applied only to the source electrode 5, and no voltage is applied between the drain electrode 6 and the terminal electrode 22, so that the capacitor is not configured.

On the other hand, in the variable capacitance element 200, when the switch part 10 is in an ON state, a gate voltage equal to or higher than the threshold value is applied to the gate electrode 2, and a channel is formed, so that the source electrode 5 and the drain electrode 6 are electrically connected. Therefore, in the variable capacitance element 200, a voltage is applied to the source electrode 5 and the drain electrode 6, and a voltage is also applied between the drain electrode 6 and the terminal electrode 22, so that the capacitor is configured.

That is, in the variable capacitance element 200, the switch part 10 operates in an ON/OFF manner to switch between a state with no capacitor and a state with a capacitor, thereby turning the capacitor ON/OFF. The variable capacitance element 200 is divided into the switch part 10 that operates in an ON/OFF manner by the voltage applied to the gate electrode 2 (control electrode terminal 2a), and the element part 20C that operates between a part of the drain electrode 6 and the terminal 22a of the terminal electrode 22 (second terminal electrode) through the terminal electrode 5a (first terminal electrode), and operates with three terminals.

As described above, in the variable capacitance element 200 according to the second exemplary embodiment, the terminal electrode 22 is formed on the surface of the dielectric layer 3a on the same side as the surface of the gate insulating film 3 on which the gate electrode 2 is formed, and a part of the drain electrode 6 is formed on the surface of the dielectric layer 3a on the side opposite to the surface of the gate insulating film 3 on which the gate electrode 2 is formed.

As a result, the variable capacitance element 200 according to the first exemplary embodiment configures (e.g., forms) a capacitor between a part of the drain electrode 6 and the terminal electrode 22 with the dielectric layer 3a sandwiched therebetween, which is formed of the same insulating film as the gate insulating film 3, so that the capacitance can be varied in a wide range including when the capacitance is zero.

### Modification 2-1

In the variable capacitance element 200, as shown in FIG. 8, a capacitor is configured with the dielectric layer 3a provided between a part of the drain electrode 6 and the terminal electrode 22. In the variable capacitance element 200, in order to further increase the capacitance of the capacitor, a configuration in which a plurality of dielectric layers configuring the element part 20C are stacked is conceivable. FIG. 9 is a cross-sectional view illustrating a configuration of a variable capacitance element 200A according to a first modification of the second exemplary embodiment. In the variable capacitance element 200A shown in FIG. 9, the same configurations as those of the variable capacitance element 200 shown in FIG. 8 are designated by the same reference numerals, and detailed description thereof will not be repeated.

The variable capacitance element 200A shown in FIG. 9 includes the switch part 10 that configures (e.g., forms) an electric field effect transistor formed on the semiconductor substrate 1, and an element part 20D that is electrically connected to the switch part 10 and configures (e.g., forms) a passive element.

The element part 20D configures (e.g., forms) a capacitor with the dielectric layer 3a provided between a part of the drain electrode 6 and a part (terminal electrode 221) of the terminal electrode 22 and further configures (e.g., forms) a capacitor with the dielectric layer 7 provided between a part of the drain electrode 6 and a part (terminal electrode 222) of the terminal electrode 22. The terminal electrode 22 includes the terminal electrode 221 formed on the semiconductor substrate 1, the terminal electrode 222 formed on the dielectric layer 7, and a terminal electrode 223 connecting the terminal electrode 221 and the terminal electrode 222 to each other. The dielectric layers sandwiched between a part of the drain electrode 6 and a part (terminal electrodes 221 and 222) of the terminal electrode 22 include the dielectric layer 3a (first dielectric layer) formed of the same insulating film as the gate insulating film 3, and the dielectric layer 7 (second dielectric layer) formed of an insulating film different from the gate insulating film 3.

According to the exemplary aspect, the element part 20D configures (e.g., forms) a plurality of layers of capacitors by sequentially stacking a part (terminal electrode 221) of the terminal electrode 22, the dielectric layer 3a (first dielectric layer), the drain electrode 6, the dielectric layer 7 (second dielectric layer), and a part (terminal electrode 222) of the terminal electrode 22. Consequently, the variable capacitance element 200A including the element part 20D can further increase the capacitance of the capacitor. The dielectric layer 3a and the dielectric layer 7 may have the same film thickness or different film thicknesses. Further, the dielectric layer 3a and the dielectric layer 7 may be the same dielectric material or may be different dielectric materials.

In the variable capacitance element 200A, the element part 20D configures (e.g., forms) a two-layer capacitor by sequentially stacking a part (terminal electrode 221) of the terminal electrode 22, the dielectric layer 3a (first dielectric layer), the drain electrode 6, the dielectric layer 7 (second dielectric layer), and a part (terminal electrode 222) of the terminal electrode 22, but three or more layers of capacitors may be configured.

### Modification 2-2

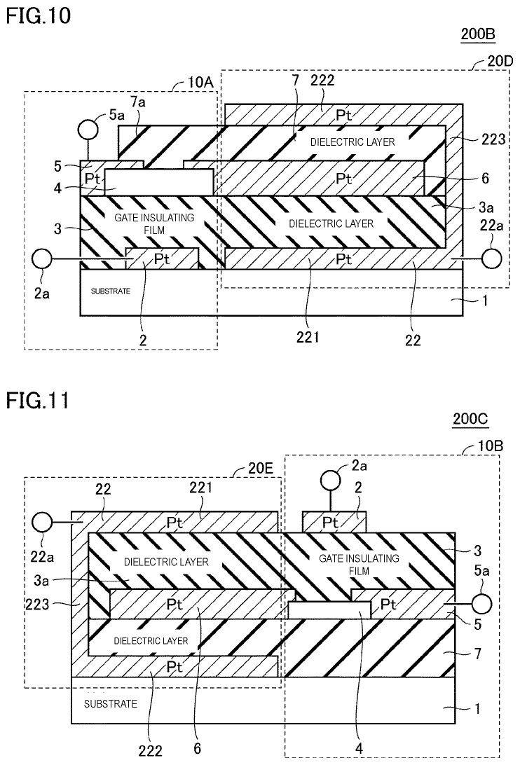

FIG. 10 is a cross-sectional view illustrating a configuration of a variable capacitance element 200B according to a second modification of the second exemplary embodiment. In the variable capacitance element 200B shown in FIG. 10, the same configurations as those of the variable capacitance element 200A shown in FIG. 9 are designated by the same reference numerals, and detailed description thereof will not be repeated.

The variable capacitance element 200B shown in FIG. 10 includes the switch part 10A that configures (e.g., forms) an electric field effect transistor formed on the semiconductor substrate 1, and the element part 20D that is electrically connected to the switch part 10A and configures (e.g., forms) a passive element.

The switch part 10A has the gate electrode 2, the gate insulating film 3, the channel forming film 4, the source electrode 5, the drain electrode 6, and the passivation film 7a. In the switch part 10A shown in FIG. 10, the gate electrode 2 is formed on the semiconductor substrate 1, the gate insulating film 3 and the channel forming film 4 are sequentially formed to overlap the gate electrode 2, and a part of the source electrode 5 and a part of the drain electrode 6 are respectively formed thereon and are covered with the passivation film 7a.

In the variable capacitance element 200B, the passivation film 7a is formed by covering the channel forming film 4 between the source electrode 5 and the drain electrode 6 with a part of the dielectric layer 7. The passivation film 7a can suppress the degradation of the characteristics of the switch part 10A. In addition, by forming the passivation film 7a using a part of the dielectric layer 7, the passivation film can be formed by covering the channel forming film 4 without adding a separate process.

### Modification 2-3

FIG. 11 is a cross-sectional view illustrating a configuration of a variable capacitance element 200C according to a third modification of the second exemplary embodiment. In the variable capacitance element 200C shown in FIG. 11, the same configurations as those of the variable capacitance element 200A shown in FIG. 9 are designated by the same reference numerals, and detailed description thereof will not be repeated.

The variable capacitance element 200C shown in FIG. 11 includes the switch part 10B that configures (e.g., forms) an electric field effect transistor formed on the semiconductor substrate 1, and an element part 20E that is electrically connected to the switch part 10B and configures (e.g., forms) a passive element.

The switch part 10B includes the gate electrode 2, the gate insulating film 3, the channel forming film 4, the source electrode 5, and the drain electrode 6. However, the switch part 10B employs the top-gate structure instead of the bottom-gate structure as in the switch part 10 shown in FIG. 9. In the switch part 10B, the channel forming film 4 is formed on the dielectric layer 7 in an overlapping manner, the source electrode 5 and the drain electrode 6 are respectively formed on the channel forming film 4, the gate insulating film 3 is formed on the source electrode 5 and the drain electrode 6, and the gate electrode 2 is formed on the gate insulating film 3.

The element part 20E configures (e.g., forms) a two-layer capacitor by sequentially stacking a part (terminal electrode 222) of the terminal electrode 22, the dielectric layer 7 (second dielectric layer), the drain electrode 6, the dielectric layer 3a (first dielectric layer), and a part (terminal electrode 221) of the terminal electrode 22.

It is noted that the variable capacitance element 200C uses the switch part 10B having the top-gate structure, but the same effect as that of the variable capacitance element 200A employing the switch part 10 having the bottom-gate structure can be obtained. In addition, a switch part having the top-gate structure may be employed for the switch part of the variable capacitance element 200 shown in FIG. 8.

### Modification 2-4

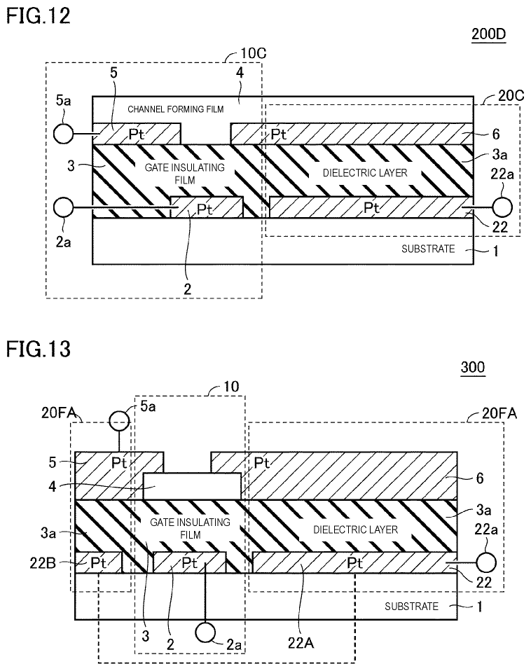

FIG. 12 is a cross-sectional view illustrating a configuration of a variable capacitance element 200D according to a fourth modification of the second exemplary embodiment. In the variable capacitance element 200D shown in FIG. 12, the same configurations as those of the variable capacitance element 200 shown in FIG. 8 are designated by the same reference numerals, and detailed description thereof will not be repeated.

A variable capacitance element 200D shown in FIG. 12 includes a switch part 10C that configures (e.g., forms) an electric field effect transistor formed on the semiconductor substrate 1, and the element part 20C that is electrically connected to the switch part 10C and configures (e.g., forms) a passive element.

The switch part 10C includes the gate electrode 2, the gate insulating film 3, the channel forming film 4, the source electrode 5, and the drain electrode 6. However, the switch part 10C has a bottom-contact structure in which the channel forming film 4 is formed on an upper side of the source electrode 5 and the drain electrode 6, instead of a top-contact structure in which the channel forming film 4 is formed on a lower side of the source electrode 5 and the drain electrode 6 as in the switch part 10 shown in FIG. 8. The bottom-contact structure is a structure in which the source electrode 5 and the drain electrode 6 are in contact with the channel forming film 4 on the lower side.

According to an exemplary aspect, the variable capacitance element 200D uses the switch part 10C having the bottom-contact structure, but the same effect as that of the variable capacitance element 200A employing the switch part 10 having the top-contact structure can be obtained. In addition, a switch part having the bottom-contact structure may be employed for the switch part of the variable capacitance element 100 shown in FIG. 1.

### Third Exemplary Embodiment

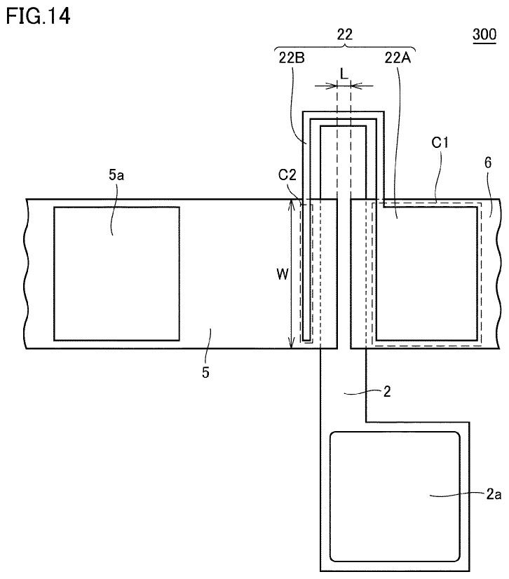

In the variable capacitance element 200 according to the second exemplary embodiment, the switch part 10 operates in an ON/OFF manner to switch between a state with no capacitor and a state with a capacitor, thereby turning the capacitor ON/OFF. In a variable capacitance element according to a third exemplary embodiment, the switch part operates in an ON/OFF manner to switch between a state in which the capacitance of the capacitor is small and a state in which the capacitance of the capacitor is large, instead of a state with no capacitor. FIG. 13 is a cross-sectional view illustrating a configuration of a variable capacitance element 300 according to the third exemplary embodiment. FIG. 14 is a plan view illustrating the configuration of the variable capacitance element 300 according to the third exemplary embodiment. In the variable capacitance element 300 shown in FIGS. 13 and 14, the same configurations as those of the variable capacitance element 200 shown in FIG. 8 are designated by the same reference numerals, and detailed description thereof will not be repeated.

The variable capacitance element 300 shown in FIG. 13 includes the switch part 10 that configures (e.g., forms) an electric field effect transistor formed on the semiconductor substrate 1, and an element part 20FA that is electrically connected to the switch part 10 and configures (e.g., forms) a passive element. The element part 20FA and the switch part 10 are horizontally disposed on the semiconductor substrate 1.

The element part 20FA includes the dielectric layer 3a and the terminal electrode 22 (second terminal electrode) formed to overlap the dielectric layer 3a. The terminal electrode 22 is formed in a pattern in which the terminal electrode 22 avoids a channel region formed between the source electrode 5 and the drain electrode 6 as shown in FIG. 14. Therefore, in the cross-sectional view shown in FIG. 13, the terminal electrode 22 is provided not only as a terminal electrode 22A formed below the drain electrode 6 but also as a terminal electrode 22B formed below the source electrode 5.

The element part 20FA configures (e.g., forms) a first capacitor between the drain electrode 6 and the terminal electrode 22A and configures (e.g., forms) a second capacitor between the source electrode 5 and the terminal electrode 22B. The first capacitor is a portion C1 in which the drain electrode 6 and the terminal electrode 22A overlap each other in a plan view as shown in FIG. 14. The second capacitor is a portion C2 in which the source electrode 5 and the terminal electrode 22B overlap each other in a plan view.

In the variable capacitance element 300, when the switch part 10 is in an OFF state, a gate voltage equal to or higher than a threshold value is not applied to the gate electrode 2, so that an electron depletion layer is present at a position of the channel forming film 4 overlapping the gate electrode 2 in a plan view, and the source electrode 5 and the drain electrode 6 are not electrically connected. Therefore, the variable capacitance element 300 has only the capacitance of the second capacitor because a voltage is applied only between the source electrode 5 and a portion of the terminal electrode 22B facing the source electrode 5.

However, in the variable capacitance element 300, when the switch part 10 is in an ON state, a gate voltage equal to or higher than the threshold value is applied to the gate electrode 2, and a channel is formed, so that the source electrode 5 and the drain electrode 6 are electrically connected. Therefore, the variable capacitance element 300 has a combined capacitance of the first capacitor and the second capacitor because a voltage is applied between the source electrode 5 and the drain electrode 6, and the facing terminal electrode 22.

As shown in FIG. 14, the variable capacitance element 300 need not be formed in a pattern in which the terminal electrode 22 bypasses the entire portion of the channel region formed between the source electrode 5 and the drain electrode 6, and may be formed in a pattern in which the terminal electrode 22 overlaps a part of the channel region.

As described above, in the variable capacitance element 300, a part (terminal electrode 22B) of the terminal electrode 22 faces a part of the source electrode 5 with the dielectric layer 3a sandwiched therebetween. As a result, the variable capacitance element 300 is configured to switch the state of the element part 20FA between a state of the second capacitor and a state of the first capacitor+the second capacitor through the ON/OFF of the switch part 10.

### Modification 3-1

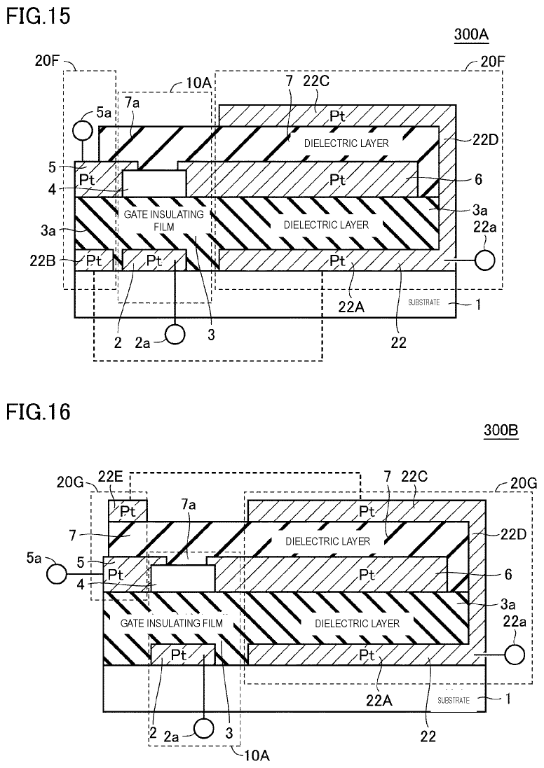

In the variable capacitance element 300, as shown in FIG. 13, a capacitor is configured with the dielectric layer 3a provided between the drain electrode 6 and the terminal electrode 22A and between the source electrode 5 and the terminal electrode 22B. In the variable capacitance element 300, in order to further increase the capacitance of the capacitor, a configuration in which a plurality of dielectric layers configuring the element part 20FA are stacked is conceivable. FIG. 15 is a cross-sectional view illustrating a configuration of a variable capacitance element 300A according to a first modification of the third exemplary embodiment. In the variable capacitance element 300A shown in FIG. 15, the same configurations as those of the variable capacitance element 300 shown in FIG. 13 are designated by the same reference numerals, and detailed description thereof will not be repeated.

The variable capacitance element 300A shown in FIG. 15 includes the switch part 10A that configures (e.g., forms) an electric field effect transistor formed on the semiconductor substrate 1, and an element part 20F that is electrically connected to the switch part 10A and configures (e.g., forms) a passive element.

A first capacitor of the element part 20F includes a capacitor configured with the dielectric layer 3a provided between a part of the drain electrode 6 and a part (terminal electrode 22A) of the terminal electrode 22 and a capacitor configured with the dielectric layer 7 provided between a part of the drain electrode 6 and a part (terminal electrode 22C) of the terminal electrode 22. The terminal electrode 22 includes the terminal electrode 22A formed on the semiconductor substrate 1, the terminal electrode 22C formed on the dielectric layer 7, and a terminal electrode 22D connecting the terminal electrode 22A and the terminal electrode 22C to each other. The dielectric layers sandwiched between a part of the drain electrode 6 and a part (terminal electrodes 22A and 22C) of the terminal electrode 22 include the dielectric layer 3a (first dielectric layer) formed of the same insulating film as the gate insulating film 3, and the dielectric layer 7 (second dielectric layer) formed of an insulating film different from the gate insulating film 3.

The first capacitor of the element part 20F configures (e.g., forms) a plurality of layers of capacitors by sequentially stacking a part (terminal electrode 22A) of the terminal electrode 22, the dielectric layer 3a (first dielectric layer), the drain electrode 6, the dielectric layer 7 (second dielectric layer), and a part (terminal electrode 22C) of the terminal electrode 22. Consequently, the variable capacitance element 300A including the element part 20F can further increase the capacitance of the capacitor. The dielectric layer 3a and the dielectric layer 7 may have the same film thickness or different film thicknesses. Further, the dielectric layer 3a and the dielectric layer 7 may be the same dielectric material or may be different dielectric materials.

In the variable capacitance element 300A, the first capacitor of the element part 20F configures (e.g., forms) a two-layer capacitor by sequentially stacking a part (terminal electrode 22A) of the terminal electrode 22, the dielectric layer 3a (first dielectric layer), the drain electrode 6, the dielectric layer 7 (second dielectric layer), and a part (terminal electrode 22C) of the terminal electrode 22, but three or more layers of capacitors may be configured.

### Modification 3-2

FIG. 16 is a cross-sectional view illustrating a configuration of a variable capacitance element 300B according to a second modification of the third exemplary embodiment. In the variable capacitance element 300B shown in FIG. 16, the same configurations as those of the variable capacitance element 300A shown in FIG. 15 are designated by the same reference numerals, and detailed description thereof will not be repeated.

The variable capacitance element 300B shown in FIG. 16 includes the switch part 10A that configures (e.g., forms) an electric field effect transistor formed on the semiconductor substrate 1, and an element part 20G that is electrically connected to the switch part 10A and configures (e.g., forms) a passive element.

A second capacitor of the element part 20G is not a capacitor configured with the dielectric layer 3a provided between the source electrode 5 and a part (terminal electrode 22B) of the terminal electrode 22 but is a capacitor configured with the dielectric layer 7 provided between the source electrode 5 and a part (terminal electrode 22E) of the terminal electrode 22. In the second capacitor of the element part 20G, the dielectric layer 7 formed on the drain electrode 6 is extended onto the source electrode 5, and the terminal electrode 22E is formed at a position overlapping the source electrode 5 in a plan view.

That is, a part (terminal electrode 22E) of the terminal electrode 22 faces a part of the source electrode 5 with the dielectric layer 7 sandwiched therebetween. The terminal electrode 22E is electrically connected to the terminal electrode 22C by bypassing the channel region. In addition, the dielectric layer 7 configures (e.g., forms) the passivation film 7a that covers the channel forming film 4 between the source electrode 5 and the drain electrode 6.

According to an exemplary aspect, the second capacitor of the element part 20G may be further provided with the terminal electrode 22B. When the terminal electrode 22B is provided, the second capacitor of the element part 20G configures (e.g., forms) a two-layer capacitor by sequentially stacking a part (terminal electrode 22B) of the terminal electrode 22, the dielectric layer 3a (first dielectric layer), a part of the source electrode 5, the dielectric layer 7 (second dielectric layer), and a part (terminal electrode 22E) of the terminal electrode 22.

### Modification 3-3

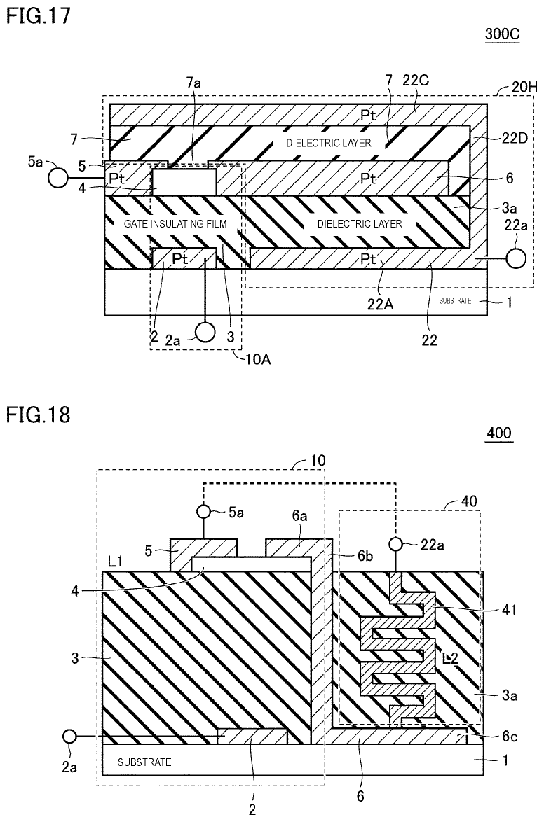

FIG. 17 is a cross-sectional view illustrating a configuration of a variable capacitance element 300C according to a third modification of the third exemplary embodiment. In the variable capacitance element 300C shown in FIG. 17, the same configurations as those of the variable capacitance element 300A shown in FIG. 15 are designated by the same reference numerals, and detailed description thereof will not be repeated.

The variable capacitance element 300C shown in FIG. 17 includes the switch part 10A that configures (e.g., forms) an electric field effect transistor formed on the semiconductor substrate 1, and an element part 20H that is electrically connected to the switch part 10A and configures (e.g., forms) a passive element.

The element part 20H is formed by extending the dielectric layer 7 formed on the drain electrode 6 onto the source electrode 5 and further extending the terminal electrode 22C onto the source electrode 5. That is, the element part 20H is formed by extending the terminal electrode 22C onto the source electrode 5 without bypassing the channel region, unlike the element part 20G shown in FIG. 16. Therefore, a part of the terminal electrode 22C faces the channel forming film 4 with the dielectric layer 7 sandwiched therebetween.

The element part 20H may be further provided with the terminal electrode 22B. When the terminal electrode 22B is provided, the second capacitor of the element part 20H configures (e.g., forms) a two-layer capacitor by sequentially stacking a part (terminal electrode 22B) of the terminal electrode 22, the dielectric layer 3a (first dielectric layer), a part of the source electrode 5, the dielectric layer 7 (second dielectric layer), and a part (a part of the terminal electrode 22C) of the terminal electrode 22.

### Fourth Exemplary Embodiment

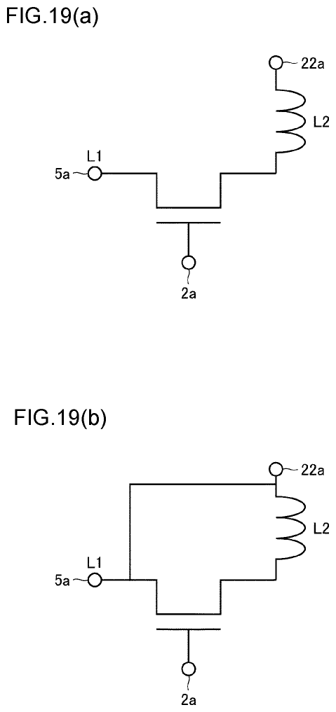

In the electronic elements according to first to third exemplary embodiments, the variable capacitance element in which the provided passive element is a capacitor and the physical quantity to be varied is the capacitance has been described, but it is noted that the provided passive element is not limited to the capacitor. For instance, in an electronic element according to a fourth exemplary embodiment, a variable inductance element in which the provided passive element is an inductor and the physical quantity to be varied is inductance will be described with reference to the drawings. FIG. 18 is a cross-sectional view illustrating a configuration of a variable inductance element 400 according to the fourth exemplary embodiment. FIG. 19(a)-FIG. 19(b) are equivalent circuit diagrams of the variable inductance element 400 according to the fourth exemplary embodiment. In the variable inductance element 400 shown in FIGS. 18 and 19 (a)-(b), the same configurations as those of the variable capacitance element 100 shown in FIG. 1 are designated by the same reference numerals, and detailed description thereof will not be repeated. In addition, in the variable inductance element 400, the same material can be used for the same configuration as that of the variable capacitance element 100.

The variable inductance element 400 shown in FIG. 18 includes the switch part 10 that configures (e.g., forms) an electric field effect transistor, and an element part 40 that is electrically connected to the switch part 10 and configures (e.g., forms) a passive element. The element part 40 is provided on the right side of the switch part 10 in the drawing.

The switch part 10 has the gate electrode 2, the gate insulating film 3, the channel forming film 4, the source electrode 5, and the drain electrode 6. In the switch part 10 shown in FIG. 18, the gate electrode 2 is formed on the semiconductor substrate 1, the gate insulating film 3 and the channel forming film 4 are sequentially formed to overlap the gate electrode 2, and a part of the source electrode 5 and a part of the drain electrode 6 are respectively formed thereon.

In the variable inductance element 400, the element part 40 is an inductor, and one end of a coil electrode 41 is electrically connected to a part (the upper portion of the electrode 6c) of the drain electrode 6. The coil electrode 41 is formed by being stacked in the dielectric layer 3a formed of the same insulating film as the gate insulating film 3, and the other end is electrically connected to the terminal 22a. That is, the element part 40 has the terminal electrode 5a (first terminal electrode) that is electrically connected to the source electrode 5, and the terminal 22a (second terminal electrode) that configures (e.g., forms) an inductor (coil electrode 41) between the terminal 22a and a part of the drain electrode 6 with the dielectric layer 3a interposed therebetween. In the variable inductance element 400, the switch part 10 is a first inductor L1, and the element part 40 is a second inductor L2. Since the first inductor L1 does not include a coil electrode, the first inductor L1 has an inductance equal to or less than a predetermined quantity (for example, equal to or less than one-ten-thousandth), which can be considered as zero. On the other hand, since the second inductor L2 includes the coil electrode 41, the second inductor L2 has inductance due to the coil electrode 41.

Similar to the variable capacitance element 100, in the variable inductance element 400, when the switch part 10 is in an OFF state, a gate voltage equal to or higher than a threshold value is not applied to the gate electrode 2, so that an electron depletion layer is present at a position of the channel forming film 4 overlapping the gate electrode 2 in a plan view, and the source electrode 5 and the drain electrode 6 are not electrically connected. Therefore, the variable inductance element 400 has only the inductance of the first inductor L1.

On the other hand, in the variable inductance element 400, when the switch part 10 is in an ON state, a gate voltage equal to or higher than the threshold value is applied to the gate electrode 2, and a channel is formed, so that the source electrode 5 and the drain electrode 6 are electrically connected. Therefore, the variable inductance element 400 has the inductance of the second inductor L2 because an electric current flows through the coil electrode 41 between the drain electrode 6 and the terminal 22a.

That is, in the variable inductance element 400, the switch part 10 operates in an ON/OFF manner to switch between a state with no inductor and a state with an inductor, thereby turning the inductor ON/OFF. The variable inductance element 400 is divided into the switch part 10 that operates in an ON/OFF manner by the voltage applied to the gate electrode 2 (control electrode terminal 2a), and the element part 40 that operates between a part (electrode 6c) of the drain electrode 6 and the terminal 22a of the terminal electrode 22 (second terminal electrode) through the terminal electrode 5a (first terminal electrode), and operates with three terminals.

As can be seen from the equivalent circuit diagram shown in FIG. 19(a), in the variable inductance element 400, while the terminal electrode 5a (first terminal electrode) and the terminal 22a (second terminal electrode) are connected to a converter circuit or the like, the control electrode terminal 2a for varying the inductance is connected to a circuit different from the converter circuit. Therefore, the probability of a signal applied to the control electrode terminal 2a being affected by the signal of the converter circuit is low. In the variable inductance element 400, the terminal electrode 5a (first terminal electrode) and the terminal 22a (second terminal electrode) may be electrically connected to each other with a wiring line as shown in the equivalent circuit diagram of FIG. 19(b).

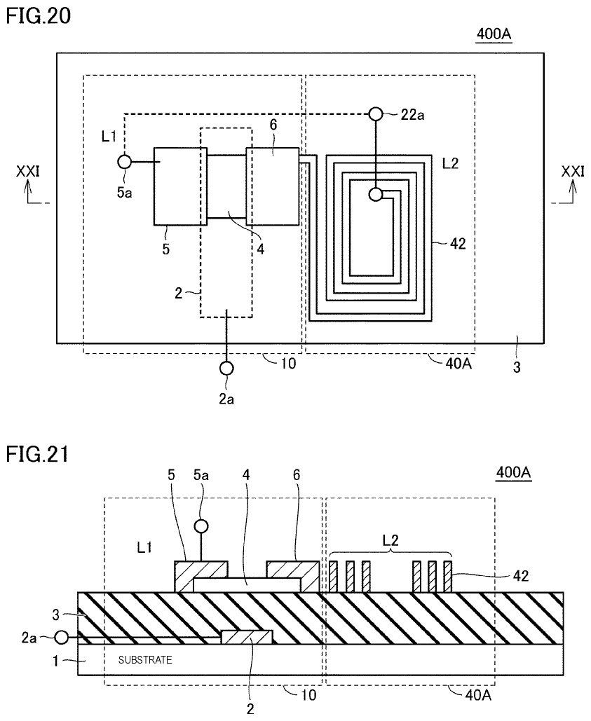

In the variable inductance element 400, as shown in FIG. 18, the second inductor L2 is formed by stacking the coil electrode 41 in the dielectric layer 3a, but the coil electrode may be formed on the dielectric layer 3a in a planar manner. FIG. 20 is a plan view illustrating a configuration of a variable inductance element 400A according to a modification of the fourth exemplary embodiment. FIG. 21 is a cross-sectional view illustrating the configuration of the variable inductance element 400A according to the modification of the fourth exemplary embodiment. In the variable inductance element 400A shown in FIGS. 20 and 21, the same configurations as those of the variable capacitance element 100 shown in FIG. 1 and the variable inductance element 400 shown in FIG. 18 are designated by the same reference numerals, and detailed description thereof will not be repeated. In addition, in the variable inductance element 400A, the same material can be used for the same configuration as that of the variable capacitance element 100.

In the variable inductance element 400A, an element part 40A is an inductor, and one end of a coil electrode 42 is electrically connected to the drain electrode 6. The coil electrode 42 is formed on the dielectric layer 3a, which is formed of the same insulating film as the gate insulating film 3, in a planar manner, and the other end is electrically connected to the terminal 22a. That is, the element part 40A has the terminal electrode 5a (first terminal electrode) that is electrically connected to the source electrode 5, and the terminal 22a (second terminal electrode) that configures (e.g., forms) an inductor (coil electrode 42) between the terminal 22a and a part of the drain electrode 6 by being in contact with the dielectric layer 3a. In the variable inductance element 400A, the switch part 10 is the first inductor L1, and the element part 40A is the second inductor L2. Since the second inductor L2 includes the coil electrode 42, the second inductor L2 has inductance due to the coil electrode 42.

As described above, the variable inductance elements 400 and 400A according to the fourth exemplary embodiment include the switch part 10 that configures (e.g., forms) an electric field effect transistor, and the element parts 40 and 40A that are electrically connected to the switch part 10 and configure an inductor. The switch part 10 has the source electrode 5, the drain electrode 6, the channel forming film 4 formed to overlap at least a part of the source electrode 5 and a part of the drain electrode 6, the gate insulating film 3 formed to overlap the channel forming film 4, and the gate electrode 2 formed to overlap the gate insulating film 3. The element parts 40 and 40A have the terminal electrode 5a (first terminal electrode) that is electrically connected to the source electrode 5, and the terminal 22a (second terminal electrode) that configures (e.g., forms) an inductor between the terminal 22a and the drain electrode 6 with the coil electrodes 41 and 42.

As a result, the variable inductance elements 400 and 400A according to the fourth exemplary embodiment configure an inductor between the drain electrode 6 and the terminal 22a, so that the inductance can be varied in a wide range including a case where the inductance is zero.

A multivalued variable inductance element may be configured by forming a plurality of the variable inductance elements 400 and 400A in a matrix shape. In addition, by changing the coil electrode 41 shown in FIG. 18 to a resistor element, a variable resistor element may be used with the passive element as a resistor. Further, the configuration of the switch part 10 may be, for example, a silicon MOSFET, a GaNFET, or the like.

In addition, in the variable inductance element 400, instead of the capacitor configured by sandwiching the dielectric layer between a part (electrode 6c) of the drain electrode and the second terminal electrode (terminal electrode 22) of the variable capacitance element 100 shown in FIG. 1, the inductor configured with the coil electrode 41 connecting a part (electrode 6c) of the drain electrode and the second terminal electrode (terminal 22a) is employed. Similarly, the variable inductance element may be used by employing the inductor, instead of the portions configuring the capacitor in the variable capacitance elements 100A to 100C, 200, 200A to 200D, 300, and 300A to 300C. In addition, the variable resistor element may be used by employing the resistor, instead of the portions configuring the capacitor in the variable capacitance elements 100A to 100C, 200, 200A to 200D, 300, and 300A to 300C. Different types of passive elements (capacitors, inductors, and resistors) may be provided in different dielectrics in the variable capacitance elements 100A to 100C, 200A to 200C, and 300A to 300C.

### Fifth Exemplary Embodiment

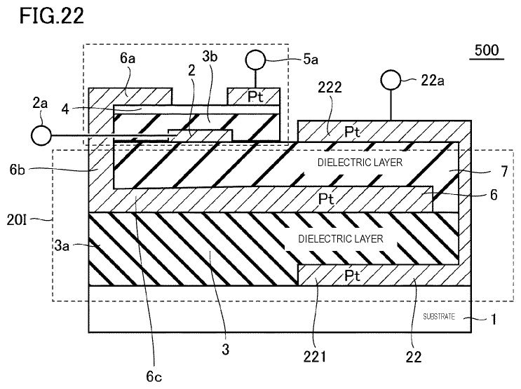

In the variable capacitance element 100A shown in FIG. 5, the variable capacitance element in which two layers of the dielectric layer 3a and the dielectric layer 7 are stacked on the semiconductor substrate 1 has been described, but it is noted that three or more dielectric layers can be stacked on the semiconductor substrate 1 in an exemplary aspect. In particular, an electronic element according to a fifth exemplary embodiment, a variable capacitance element in which three dielectric layers are stacked on the substrate will be described with reference to the drawings. Of course, the variable capacitance element may be formed by stacking four or more dielectric layers on the substrate. FIG. 22 is a cross-sectional view illustrating a configuration of a variable capacitance element 500 according to the fifth exemplary embodiment. In the variable capacitance element 500 shown in FIG. 22, the same configurations as those of the variable capacitance elements 100, 100A, and the like shown in FIG. 1 are designated by the same reference numerals, and detailed description thereof will not be repeated. In addition, in the variable capacitance element 500, the same material can be used for the same configuration as that of the variable capacitance elements 100, 100A, and the like.

In the variable capacitance element 500 shown in FIG. 22, the dielectric layer 3a (first dielectric layer), the dielectric layer 7 (second dielectric layer), and a dielectric layer 3b (third dielectric layer) are stacked on the semiconductor substrate 1, and the switch part 10 that configures (e.g., forms) an electric field effect transistor is provided with the dielectric layer 3b. Further, in the variable capacitance element 500, an element part 20I that is electrically connected to the switch part 10 and configures (e.g., forms) a capacitor is provided with the dielectric layer 3a and the dielectric layer 7. The element part 20I and the switch part 10 are vertically disposed on the semiconductor substrate 1.

The switch part 10 has the gate electrode 2, the dielectric layer 3b that configures (e.g., forms) the gate insulating film, the channel forming film 4, the source electrode 5, and the drain electrode 6. In the switch part 10 shown in FIG. 22, the gate electrode 2 is formed on the dielectric layer 3b (third dielectric layer), the channel forming film 4 is formed to overlap the dielectric layer 3b in which the gate electrode 2 is formed, and the source electrode 5 and a part (electrode 6a) of the drain electrode 6 are formed thereon.

The element part 20I configures (e.g., forms) a plurality of layers of capacitors by sequentially stacking a part (terminal electrode 221) of the terminal electrode 22, the dielectric layer 3a (first dielectric layer), a part (electrode 6c) of the drain electrode 6, the dielectric layer 7 (second dielectric layer), and a part (terminal electrode 222) of the terminal electrode 22. Consequently, the variable capacitance element 500 including the element part 20I can further increase the capacitance of the capacitor. The dielectric layer 7 (second dielectric layer) and the dielectric layer 3b (third dielectric layer) configuring the gate insulating film are the same insulating film (dielectric material). Of course, the dielectric layer 7 and the dielectric layer 3b may be made of the same dielectric material as that of the dielectric layer 3a (that is, all the dielectric layers may be made of the same dielectric material). Further, the dielectric layer 3a and the dielectric layer 3b may be made of the same dielectric material, the dielectric layer 3a and the dielectric layer 7 may be made of the same dielectric material, and the dielectric layers 3a and 3b and the dielectric layer 7 may all be made of different dielectric materials. In addition, the dielectric layers 3a and 3b and the dielectric layer 7 may have the same film thickness or may have different film thicknesses.

In the variable capacitance element 500, in the element part 20I, the switch part 10 is formed using the dielectric layer 3b (third dielectric layer) among the dielectric layers 3a, 3b, and 7 stacked in three layers on the semiconductor substrate 1, and the element part 20I of the two-layer capacitor is configured with the remaining two layers of the dielectric layers 3a and 7, but the element part 20I may be configured with three or more layers of capacitors.

When the switch part 10 is in an OFF state, a gate voltage equal to or higher than a threshold value is not applied to the gate electrode 2, so that an electron depletion layer is present at a position of the channel forming film 4 overlapping the gate electrode 2 in a plan view, and the source electrode 5 and the drain electrode 6 are not electrically connected. Therefore, in the variable capacitance element 500, a voltage is applied only to the source electrode 5, and no voltage is applied between the electrode 6c and the terminal electrode 22, so that the capacitor is not configured.

On the other hand, in the variable capacitance element 500, when the switch part 10 is in an ON state, a gate voltage equal to or higher than the threshold value is applied to the gate electrode 2, and a channel is formed, so that the source electrode 5 and the drain electrode 6 are electrically connected. Therefore, in the variable capacitance element 500, a voltage is applied to the source electrode 5 and the drain electrode 6, and a voltage is also applied between the electrode 6c and the terminal electrode 22, so that the capacitor is configured.

In the configuration of the variable capacitance element 500 shown in FIG. 22, a variable inductance element may be used by employing the inductor instead of the portion configuring the capacitor, or a variable resistor element may be used by employing the resistor instead of the portion configuring the capacitor.

### Exemplary Modifications

It is noted that materials that can be employed for the gate insulating film 3 and the dielectric layers 3a and 7 are summarized and listed below. However, it should be appreciated that the materials are not limited to the following description.
Amorphous or polycrystalline metal oxides such as SiO₂, Al₂O₃, HfO₂, ZrO₂, La₂O₃, and Ta₂O₅
Nitride films such as SiN, Si₃N₄, and SiON
A ferroelectric HfO₂ and a ferroelectric film in which HfO₂ is doped with at least one trivalent, tetravalent, or pentavalent metal atom such as Si, Ce, Y, Zr, Bi, Ni, Ta, and La, ferroelectric materials with PbTiO₃ as base crystals, ferroelectric materials with (Ba, Sr) TiO₃ as base crystals, ferroelectric materials having a Bi layered structure, metal oxides having other perovskite-type crystals, metal oxides having pyrochlore-type crystals, organic ferroelectric materials, and other resin materials (polyimide, acrylic, epoxy, polypropylene, polyester, polyethylene terephthalate, polyethylene naphthalate, polyphenylene sulfide, polylactic acid, and the like)

It is also noted that materials that can be employed for the channel forming film 4 are summarized and listed below. However, it should be appreciated that the materials are not limited to the following description.
In—O, In—Sn—O, In—Zn—O, In—Sn—Zn—O, In—Ga—Zn—O, In—Ga—O, Ga—O, Zn—O, Al—Zn—O, Sn—O, and Ti—O-based n-type oxide semiconductors
Cu—O, Sn—O, and Zn—O-based p-type oxide semiconductors
Cu—Sn—I-based amorphous p-type oxide semiconductors
Si semiconductors such as n-type Si, p-type Si, and Sic
Nitride semiconductors such as GaN
Graphene and transition metal chalcogenide-based two-dimensional conductive materials
Perovskite-type conductive materials such as LaNiO₃, BaSnO₃, and SrTiO₃

In general, the above-mentioned variable capacitance elements 100, 200, 300, and the like can be applied to various circuit devices as should be appreciated to those skilled in the art. The circuit device includes a circuit wiring line and the above-mentioned variable capacitance elements 100, 200, and 300 electrically connected to the circuit wiring line. For example, the above-mentioned variable capacitance elements 100, 200, 300, and the like can be applied to circuit devices such as an LLC resonance converter, a communication circuit provided in a wireless communication terminal, and a hybrid switch circuit used for a DC circuit breaker.

### REFERENCE SIGNS LIST

1 SEMICONDUCTOR SUBSTRATE
2 GATE ELECTRODE
2a CONTROL ELECTRODE TERMINAL
3 GATE INSULATING FILM
3a, 7 DIELECTRIC LAYER
4 CHANNEL FORMING FILM
5 SOURCE ELECTRODE
5a, 22 TERMINAL ELECTRODE
6 DRAIN ELECTRODE
10 SWITCH PART
20, 40 ELEMENT PART
41, 42 COIL ELECTRODE
100, 200, 300, 500 VARIABLE CAPACITANCE ELEMENT
400 VARIABLE INDUCTANCE ELEMENT

1. An electronic element comprising:
a switch that configures an electric field effect transistor; and
an element electrically connected to the switch and that configures a passive element,
wherein the switch includes:
a source electrode,
a drain electrode,
a channel forming film that overlaps at least a part of the source electrode and a part of the drain electrode,
a gate insulating film that overlaps the channel forming film, and
a gate electrode on the gate insulating film, wherein the element includes:
a first terminal electrode that is electrically connected to the source electrode, and
a second terminal electrode that configures the passive element between the second terminal electrode and a part of the drain electrode by sandwiching a dielectric layer therebetween or that is in contact with the dielectric layer,
wherein the dielectric layer includes a first dielectric layer that is a same film as at least the gate insulating film, and a second dielectric layer, and
wherein the element configures a plurality of layers of the passive element by sequentially stacking at least a part of the drain electrode, the first dielectric layer, the second terminal electrode, the second dielectric layer, and at least a part of the drain electrode.

2. The electronic element according to claim 1, wherein the switch and the element are horizontally disposed on a substrate.

3. The electronic element according to claim 1, wherein a part of the drain electrode is on a surface of the dielectric layer on a same side as a surface of the gate insulating film on which the gate electrode is disposed.

4. The electronic element according to claim 3, wherein the second terminal electrode is on a surface of the dielectric layer on a side opposite to the surface of the gate insulating film on which the gate electrode is disposed.

5. The electronic element according to claim 1, wherein the second terminal electrode is on a surface of the dielectric layer on a same side as a surface of the gate insulating film on which the gate electrode is disposed.

6. The electronic element according to claim 5, wherein a part of the drain electrode is on a surface of the dielectric layer on a side opposite to the surface of the gate insulating film on which the gate electrode is disposed.

7. The electronic element according to claim 1, wherein a part of the second dielectric layer covers the channel forming film between the source electrode and the drain electrode.

8. The electronic element according to claim 1, wherein a part of the second terminal electrode faces a part of the source electrode with the first dielectric layer sandwiched therebetween.

9. The electronic element according to claim 1, wherein a part of the second terminal electrode faces a part of the source electrode with the second dielectric layer sandwiched therebetween.

10. The electronic element according to claim 9, wherein a part of the second terminal electrode faces the channel forming film with the second dielectric layer sandwiched therebetween.

11. The electronic element according to claim 1, wherein the passive element is at least one of a capacitor configured by sandwiching the dielectric layer between a part of the drain electrode and the second terminal electrode, an inductor configured with a coil electrode that connects a part of the drain electrode to the second terminal electrode, and a resistor configured with a resistor element that connects a part of the drain electrode to the second terminal electrode.

12. The electronic element according to claim 1, wherein the passive element is an inductor, and the first and second terminal electrodes are connected to each other with a wiring line.

13. The electronic element according to claim 2, wherein:
an uppermost layer of the dielectric layers is configured as the gate insulating film for the switch, and
layers other than the dielectric layer are provided as the gate insulating film to configure the passive element.

14. A circuit device comprising:
a circuit wiring line; and
the electronic element according to claim 1 that is electrically connected to the circuit wiring line.

15. An electronic element comprising:
a switch that configures an electric field effect transistor; and
an element electrically connected to the switch and that configures an inductors,
wherein the switch includes:
a source electrode,
a drain electrode,
a channel forming film that overlaps at least a part of the source electrode and a part of the drain electrode,
a gate insulating film that overlaps the channel forming film, and
a gate electrode on the gate insulating film, wherein the element includes:
a first terminal electrode that is electrically connected to the source electrode, and
a second terminal electrode that configures the inductor between the second terminal electrode and a part of the drain electrode by sandwiching a dielectric layer therebetween or that is in contact with the dielectric layer, and
wherein the dielectric layer and the gate insulating film are a same insulating film, and
wherein the first terminal electrode, the drain electrode, and the second terminal electrode are on a surface of the dielectric layer on a side opposite to a surface of the gate insulating film on which the gate electrode is disposed.

16. The electronic element according to claim 15, wherein the switch and the element are horizontally disposed on a substrate.

17. The electronic element according to claim 15, wherein the dielectric layer includes a first dielectric layer that is a same film as at least the gate insulating film, and a second dielectric layer.

18. The electronic element according to claim 17, wherein a part of the second dielectric layer covers the channel forming film between the source electrode and the drain electrode.

19. The electronic element according to claim 17, wherein a part of the second terminal electrode faces a part of the source electrode with the first dielectric layer sandwiched therebetween.

20. The electronic element according to claim 17, wherein:
a part of the second terminal electrode faces a part of the source electrode with the second dielectric layer sandwiched therebetween, and
a part of the second terminal electrode faces the channel forming film with the second dielectric layer sandwiched therebetween.
